(19) United States
(12) Patent Application Publication
(10) Pub. No.: US 2002/0098637 A1
(43) Pub. Date: Jul. 25, 2002

(54) High voltage laterally diffused metal oxide semiconductor with improved on resistance and method of manufacture

(75) Inventors: Zia Hossain, Tempe, AZ (US); Mohamed Imam, Tempe, AZ (US); Evgueniy N. Stefanov, Vieille Toulouse (FR); Mohammed Tanvir Quddus, Tempe, AZ (US); Joe Fulton, Chandler, AZ (US)

Correspondence Address: Robert D. Atkins, Semiconductor Components Industries, LLC, Patent Administration Dept - MD A230, P.O. Box 62890, Phoenix, AZ, 85082-2890, US

(73) Assignee: Semiconductor Components Industries, LLC

(21) Appl. No.: 09/766,965

(22) Filed: Jan. 23, 2001

(51) Int. Cl. H01L 21/8238; H01L 21/336; H01L 21/8234

(52) U.S. Cl. 438/200

(57) ABSTRACT

A high voltage device (100) is provided that has distinct field oxide regions (122) surrounded by p-top regions (108). The device is formed by first forming a p-top region (108) and then forming a patterned field oxide layer (122) over the p-top region (108). The field oxide layer (122) has open areas where the p-top region (108) is not covered by field oxide (122). The field oxide layer (122) that overlies the p-top region (108) consumes the p-top region (108) leaving exposed p-top regions (108) between the field oxide layer (122). Alternatively, the device (100) is formed by first forming a pattern of field oxide (122) on top of the device (100). Then, an implantation step is performed to form a p-top region (108). The areas of field oxide (122) block the implant. The areas where there are openings allow the formation of p-top regions (108) between the field oxide (122).

### FIELD OF THE INVENTION

The present invention relates to high voltage metal oxide semiconductor (MOS) devices and more specifically to a method for making high voltage LDMOS with improved RDS_{ON}.

### BACKGROUND OF THE INVENTION

When designing high voltage metal oxide semiconductor (MOS) devices two criteria must be kept in mind. First, the device should have a very high breakdown voltage (V_{BD}). Second, the device, when operating, should have as low an on-resistance (RDS_{ON}) as possible. One problem is that techniques and structures that tend to maximize V_{BD} tend to adversely affect RDS_{ON} and vice versa.

To overcome this problem, different designs have been proposed to form devices with acceptable combinations of V_{BD} and RDS_{ON}. One such family of devices is fabricated according to the reduced surface field (RESURF) principle. These devices utilize an extended drain region (in one embodiment a n-well) to support high off-state voltage (V_{BD}) . These devices have a maximum charge in the drain area of about 1×10¹²cm⁻² before avalanche breakdown occurs. This maximum charge sets up the lowest RDS_{ON} possible since RDS_{ON} is proportional to the charge in the drain region.

To help alleviate this problem, some devices utilize a top layer of a conductivity type opposite the extended drain region inside the drain region (in one embodiment a p-top layer). The top layer allows for a drain region having approximately double the charge than previous designs, which decreases the RDS_{ON}. The top layer helps to deplete the extended drain when the extended drain is supporting high voltage, thus allowing for high breakdown voltage.

One drawback to this approach is that a field oxide layer is typically formed over the top layer in the extended drain layer. This is done to protect the device from mobile impurities. However, the field oxide layer tends to consume the top layer, which in turn decreases, the predictability and controllability of the top layer in working to decrease RDS_{ON}. What is needed is a device that maximizes the contributions from a top layer and the protective field oxide layer.

### BRIEF DESCRIPTION OF THE DRAWINGS

For a more complete understanding of the present invention and advantages thereof, reference is now made to the following descriptions, taken in conjunction with the following drawings, in which like reference numerals represent like parts, and in which:

FIG. 1 is a cross-sectional side view of one embodiment of the present invention;

FIG. 2 illustrates a second embodiment where most of the p-top layer under a field oxide layer is consumed;

FIG. 3 illustrates a top view of the device in accordance with the teachings of the present invention;

FIGS. 4-7 illustrate a first method for formation of the present invention;

FIGS. 8-11 illustrate a second method for formation of the present invention;

FIG. 12 illustrates an embodiment of the present invention with decreasing p-top layers;

FIG. 13 illustrates an embodiment of the present invention with layers of polysilicon formed over the p-top layers;

FIG. 14 illustrates an embodiment of the present invention with an enhanced n-well; and

FIG. 15 illustrates an embodiment of the present invention with multiple p-region layers.

### DETAILED DESCRIPTION OF THE DRAWINGS

The present invention relates to high voltage MOS devices that have a high breakdown voltage and low onresistance. While specific embodiments are described below using n-channel devices, the present invention also pertains to p-channel devices, which may be formed by reversing the conductivity of the described regions and layers

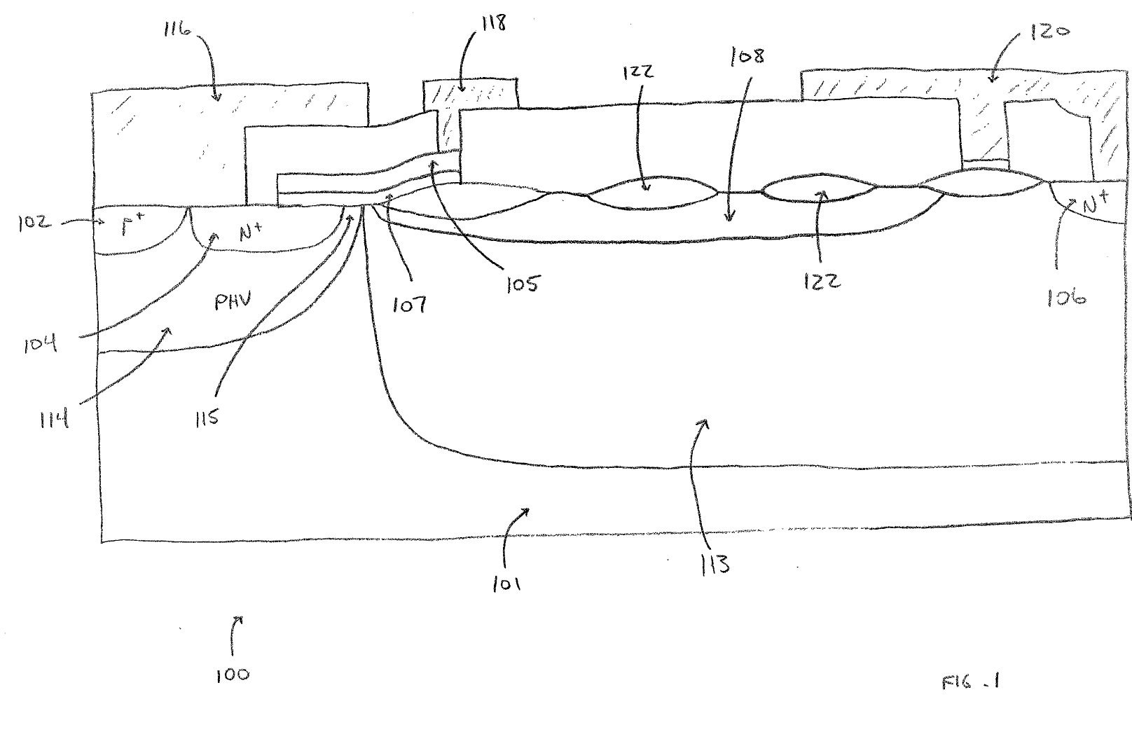

FIG. 1 illustrates an exemplary n-channel MOS device 100 showing an embodiment of the present invention. Illustrated is a lightly doped p-type substrate region 101. An N+ source diffusion region 104 is formed in substrate region 101. A P+ diffusion region 102 is formed adjacent to N+ source diffusion region 104. This P+ diffusion region 102, increases the integrity of the source to substrate connection as well as reduces the device's susceptibility to parasitic bipolar effects.

Associated with N+ source diffusion region 104 and the P+ region 102 is a source electrode 116, which provides electrical contact to the N+ source region 104 and the P+ region 102. Also illustrated is a gate 105 (typically comprising polysilicon) formed over an insulating layer 107 (comprising silicon dioxide or some other insulating dielectric material) and a gate contact 118.

A drain diffusion region 106 is connected electrically to drain contact 120. Drain contact 120 may comprise a number of conductive metals or metal alloys. An optional diffused P region 114 may be formed to enclose P+ region 102 and N+ source region 104. This diffused P region 114 is a lightly doped (high voltage) P-region (PHV) and helps to reduce the device's susceptibility to drain-to-source punch through as well as helps to provide an appropriate threshold voltage. A device including this region is known as a double diffused metal oxide device or DMOS device. When the source contact and drain contact are on the same surface, the device is known as a lateral DMOS or LDMOS. A channel region 115 exists between the N+ source region 104 and the diffused P region 114.

An n-well region 113 comprising a region of high doping concentration is formed in substrate 101. In n-well region 113, in one embodiment, the charge can approach 2×10¹²cm⁻².

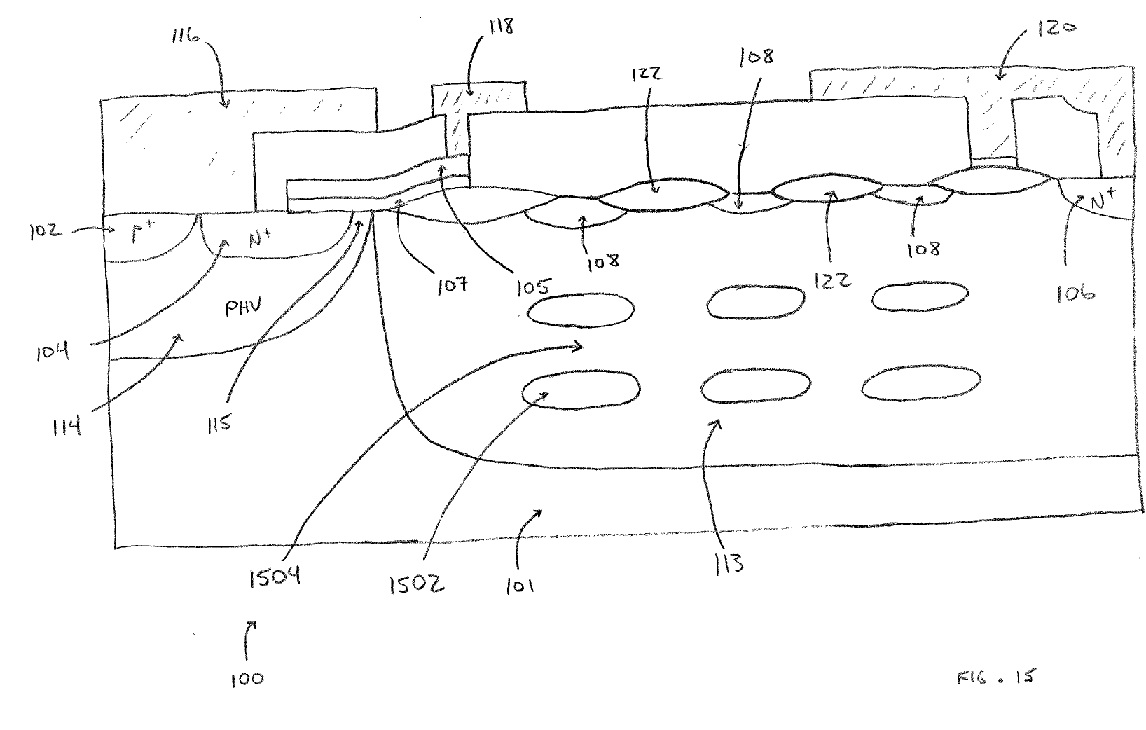

A p-top layer 108 is formed inside n-well 113 for charge balancing. P-top layer 108 may be located adjacent to the top of substrate 101 or implanted inside n-well 113. Alternatively, more than one p-top layer may be formed within n-well 113 as is further discussed in conjunction with FIG. 15. The p-top layer 108 allows for downward depletion when voltage is blocked. This, along with the upward depletion from the bottom of n-well 113, allows for a high breakdown voltage. The increased doping in the first n-well region 113 allows for lower on-resistance. While a n-well region 113 has been illustrated, alternatively an n-epi layer formed by epitaxial growth can be utilized.

In the area between the gate and drain, field oxide 122 is applied. A thick layer of field oxide 122 is typically placed over exposed areas of the n-well 113 to prevent impurities from entering the n-well 113. In this invention, instead of forming one contiguous layer of field oxide 122, field oxide 122 is applied in stripes, rectangles, or other shapes that allows for the p-top layer 108 to be partially exposed with no field oxide over certain areas of the p-top layer 108 and adjacent areas where the field oxide 122 is formed over the p-top layer 108. It is well known that the field oxide will consume at least some of the p-top layer 108 that is under the field oxide layer 122. If the field oxide 122 consumes only part of the underlying p-top layer 108, then there will be areas of thin p-top layer regions 109 underlying the field oxide layers 122 and areas of unconsumed p-top layers 108 between them. This will result in uneven doping concentration throughout p-top layer 108. It has been shown that non-uniform doping in the p-top layer 108 results in higher breakdown voltage and hence allows for lower RDS_{ON} due to the uniformity of electrical fields.

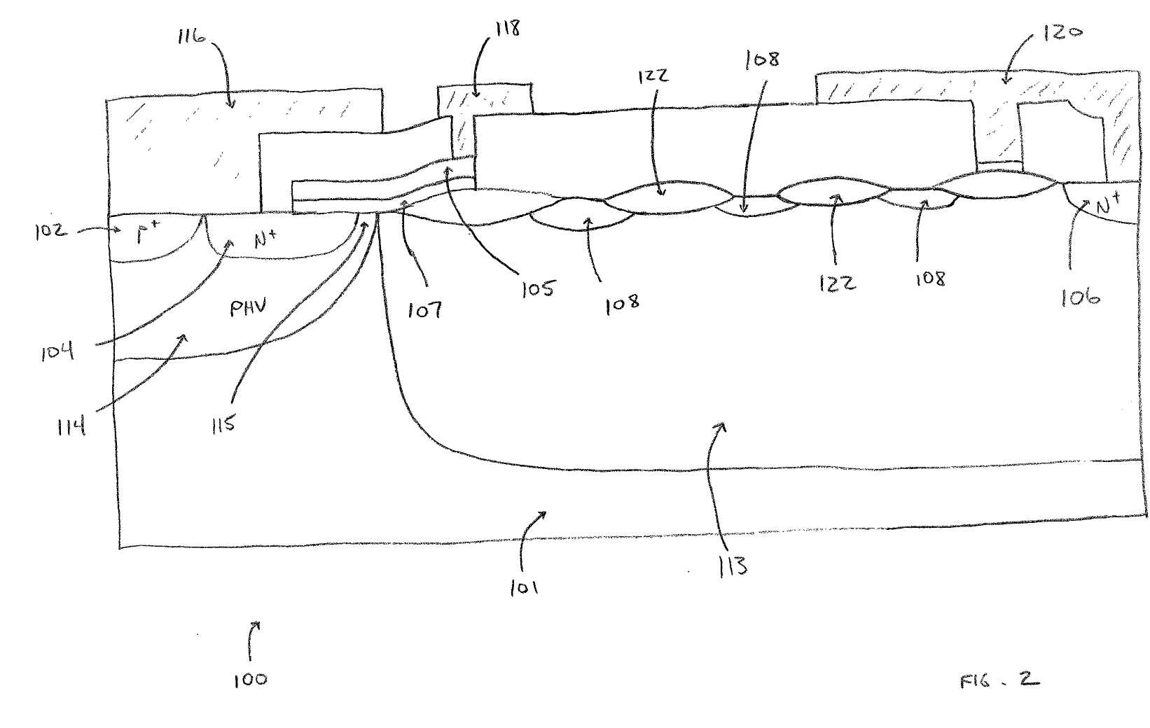

FIG. 2 illustrates a second embodiment where all of p-top layer underlying the field oxide layer 122 has been consumed. This leads to distinct p-top layers 108 surrounding the field oxide layer 122. When the device is blocking voltage, the p-top layers 108 can deplete downward and to the sides. This allows for higher breakdown voltages. The presence of p-top layers 108 allows for larger charges in the n-well, resulting in a lower on-resistance. This design leads to controllable and predictable p-top layers 108 since the distribution of the field oxide layer can be designed to enhance p-top layer 108 performance.

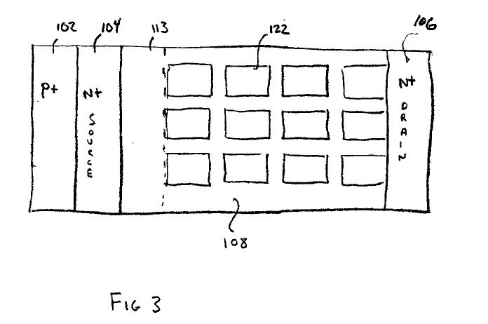

FIG. 3 illustrates a top view of device 100. Visible are source region 104, drain region 106 and p-top layer 108. Field oxide layer 122 is distributed over p-top layer 108. Field oxide layer 122 in this embodiment is illustrated as a plurality of rectangles. However, other shapes for field oxide layer 122 such as circular, hexagonal, stripes and any other shape that allows for portions of the p-top layers 108 to be exposed are feasible. P-top layers 108 are shown between field oxide region 122.

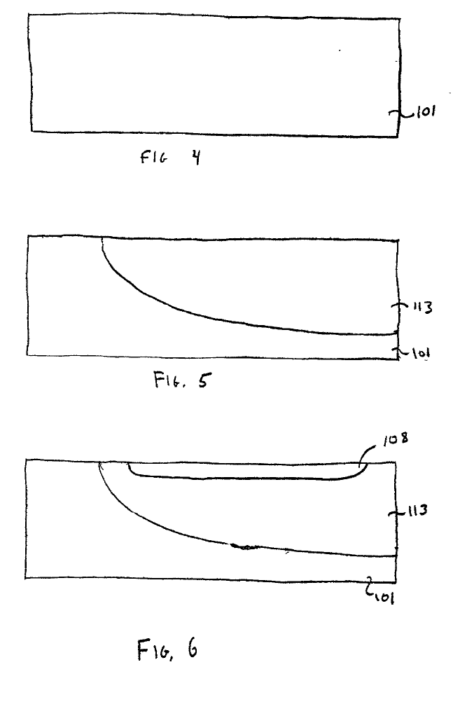

FIG. 4 illustrates a first step in a first method for formation of the present invention. In step one, a substrate is provided. In step two, a n-well region 113 is formed by implantation and is diffused using a thermal cycle. This is illustrated in FIG. 5. In step three, illustrated in FIG. 6, a p-top layer 108 is formed via an implantation step. In one embodiment, this implantation is followed by a thermal cycle to diffuse the p-top layer 108. In step four, field oxide layer 122 is applied over the p-top layer 108 in a pattern. In areas where the field oxide layer 122 overlies the p-top layer 108, the p-top layer will be at least partially consumed. In areas where the field oxide layer is not formed, the p-top layer will be essentially unaffected by the field oxide layer (some consumption may occur at the edges of p-top layers 108 near the adjacent field oxide layers 122). Sufficient amounts of uncovered p-top layers 108 can be chosen to maximize breakdown voltage and minimize on-resistance. This is illustrated in FIG. 7. The remainder of the formation of device 100 is well known in the art.

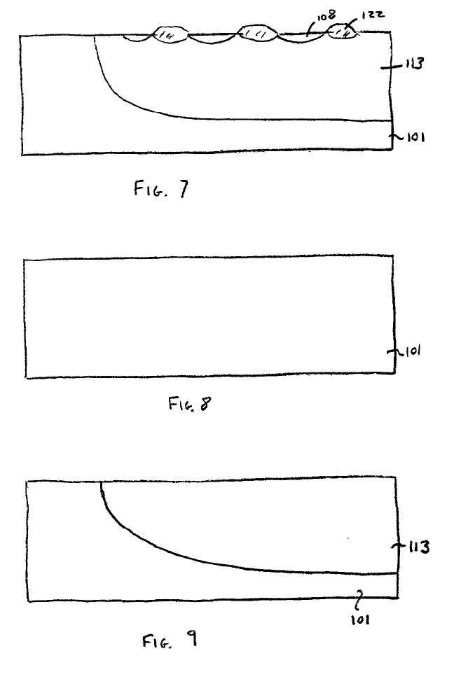

FIG. 8 illustrates a first step in a second method for formation of the present invention. In step one, a substrate is provided. In step two, n-well region 113 is formed by implantation and is diffused using a thermal cycle. This is illustrated in FIG. 9.

FIG. 10 illustrates step three of the method. In this step, field oxide layer 1002 is applied before forming the p-top layer 108. Field oxide layer 1002 is formed in a pattern having spaces between different regions of the field oxide. Field oxide region 1002 can be a striped pattern, a series of rectangles (similar to FIG. 3), a series of circles, or any other shape that allows for spacing between the field oxide layer 1002.

FIG. 11 illustrates step four. In step four after field oxide layer 1002 is applied, an implant 1102 is done to form p-top layer 108. In the case of a p-top layer region, this implant will typically be a boron implant. The field oxide layer 1002 will block the implant but the implant will penetrate into the n-well region 113 between the field oxide regions 1002. A mask 1104 is also used to prevent implantation in unwanted areas. Thus, the p-top layer 108 will be self-aligned to the field oxide region 1002. As before, the presence of the p-top layer 108 leads to the ability to deplete the extended drain region when blocking voltage and increases the breakdown voltage. The p-top layer also allows for higher dopant concentration in the n-well 113, resulting in a lower RDS_{ON}. The other structures of FIG. 1 are formed in a conventional manner.

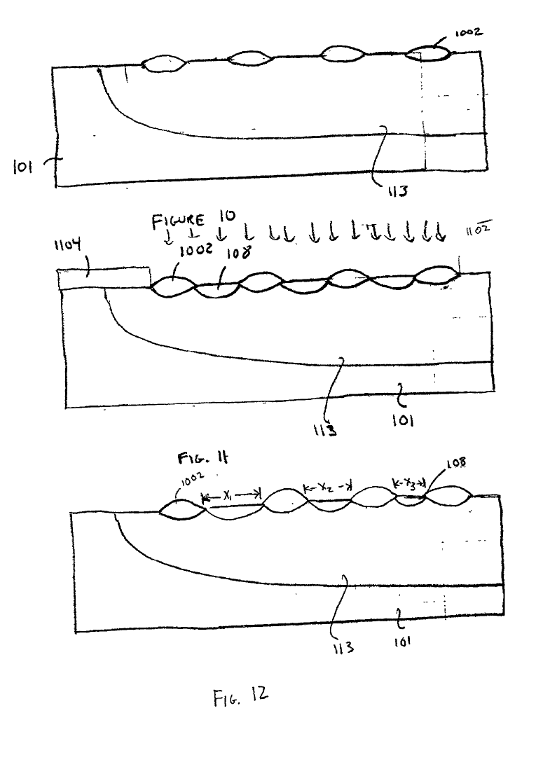

FIG. 12 illustrates an embodiment of the present invention that includes linearly varying p-top layer 108 concentrations. In this embodiment, the spacing between the field oxide regions 1002 decreases laterally as seen in FIG. 12 where X₁>X₂>X₃. This results in increasingly smaller p-top layer 108 between where the field oxide regions 1002 separation decreases. Thus, the doping in the p-top layer 108 will vary laterally. Experimentally it has been shown that by laterally varying the p-region a higher breakdown voltage and lower RDS_{ON} can be achieved.

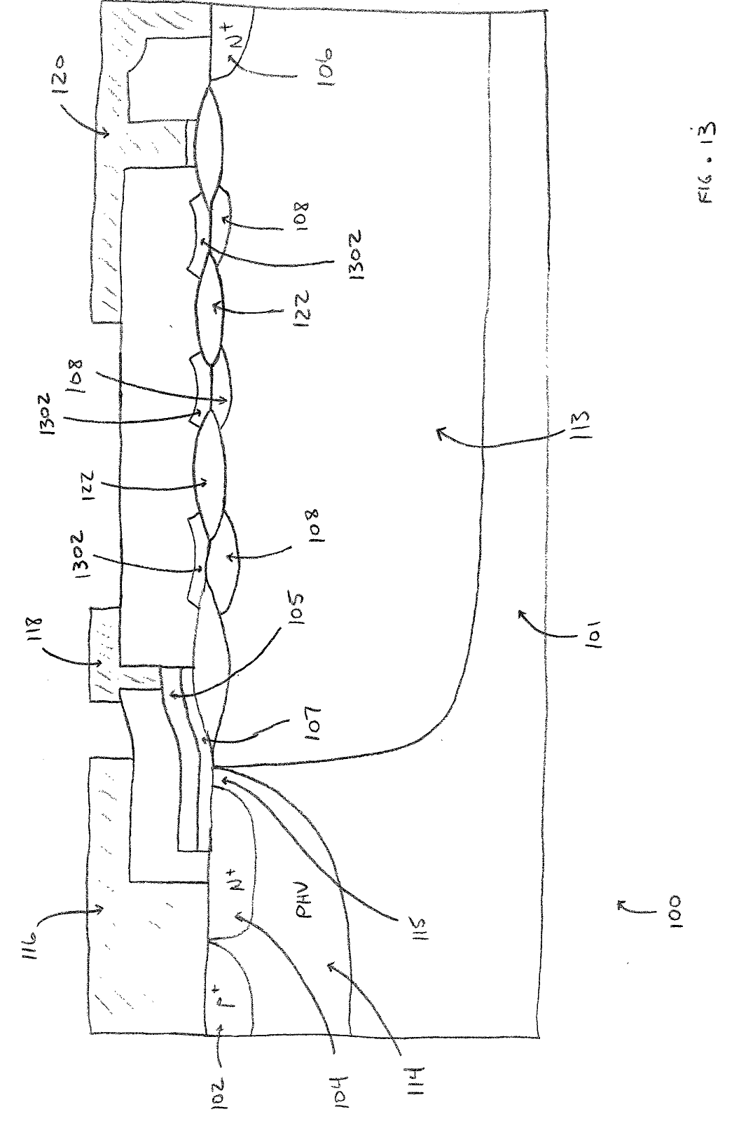

FIG. 13 illustrates an embodiment of the present invention where layers of polysilicon 1302 are applied over p-top layer 108. The layers of polysilicon 1302 can be formed in the embodiment where p-top layer 108 is formed first (FIG. 1 and FIG. 2) or in the case where the p-top layer 108 is formed after the field oxide layer 122 (FIGS. 5, 8-11). The layer of polysilicon 1302 helps to distribute the electric field and entrances the breakdown voltage. The layers of polysilicon also help to shield the p-top layers 108.

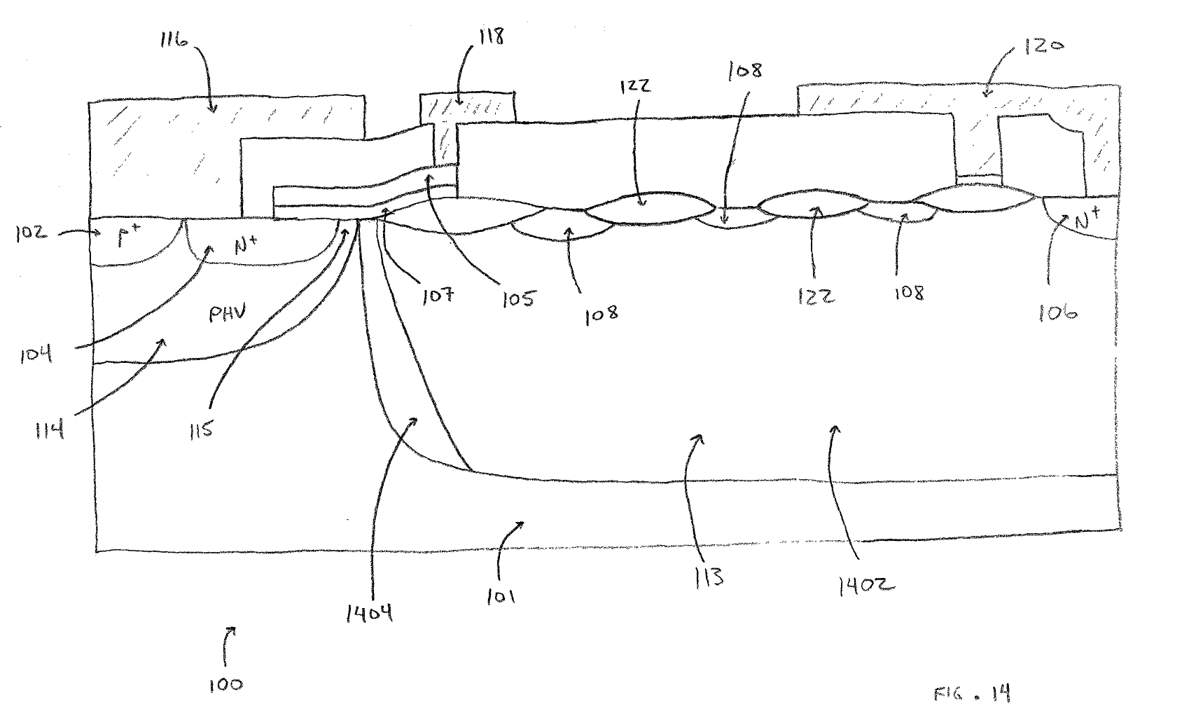

FIG. 14 illustrates a cross sectional view of an embodiment with an enhanced n-well in accordance with the teachings of the present invention. In this embodiment, n-well 113 comprises a first region 1402 of high dopant concentration offset from a second region 1404 of lower dopant concentration. The regions are formed by performing two separate n-well implants. The first implant is a relatively low concentration implant. Then, a second implant is laterally offset from the first implant by a set amount. This forms the two separate regions. This embodiment allows for a lower concentration of dopant under the gate region adjacent to the region 114, which increases the depletion extention into the n-well 113, which helps prevent premature breakdowns that occur at critical fields at the surface of the device.

FIG. 15 illustrates an alternative embodiment of the present invention. In this embodiment, additional p-regions 1502 are formed within n-well 113 and below p-top layer 108. These p-regions are formed, for example, by high-energy ion implantation. This results in an n-well 113 with multiple p-regions 1502 separated by conductivity channels 1504. These conductivity channels 1504 allow for a large charge to be supported in each conductivity channel.

Thus, it is apparent that there has been provided, in accordance with the present invention, an improved semiconductor device. It should be understood that various changes, substitutions, and alterations are readily ascertainable and can be made herein without departing from the spirit and scope of the present invention as defined by the following claims.

What is claimed is:

1. A high voltage MOS device comprising:
a substrate;
the first region of a first conductivity type formed in the substrate;
a second region of a second conductivity type comprising a plurality of subregions dispersed throughout the top of the first region; and
and a plurality of field oxide regions formed between the plurality of subregions.

2. The device of claim 1, wherein a thin layer of the second conductivity type underlies the field oxide regions.

3. The device of claim 2, wherein the thin layer of the second conductivity underlying the field oxide layer and the second region forms a region of the second conductivity type with linearly varying doping.

4. The device of claim 1, wherein the first region is an epitaxial layer.

5. The device of claim 1, wherein the first region is a well region.

6. The device of claim 5, wherein the well region comprises a first region and a second region, the first region having a higher dopant concentration than the second region.

7. The device of claim 1, further comprising a diffused region of the second conductivity type, the diffused region formed under a source region.

8. The device of claim 1, further comprising a plurality of layers of a second conductivity type formed below the second region and inside the first region.

9. The device of claim 1, wherein the plurality of oxide regions are shaped as rectangles.

10. A high voltage DMOS device comprising:
a first region of a first conductivity type formed in a substrate;
a second region of a second conductivity type formed at the top of the first region, the second region comprising a plurality of subregions dispersed throughout the top of the first region;
a plurality of field oxide islands formed between the plurality of subregions;
a drain region formed within the first region;
a lightly doped, high voltage diffused region of the second conductivity type; and
a source region formed within the lightly doped, high voltage diffused region.

11. The device of claim 10, wherein an area under the field oxide islands comprises a layer of the second conductivity type.

12. The device of claim 11, wherein the layer of the second conductivity underlying the field oxide layer and the second region forms a region of the second conductivity type with linearly varying doping.

13. The device of claim 10, wherein the first region is an epitaxial layer.

14. The device of claim 10, wherein the first region is a well region.

15. The device of claim 14, wherein the well region comprises a first region and a second region, the first region having a higher dopant concentration that the second region.

16. The device of claim 10, further comprising a diffused region of the second conductivity type, the diffused region formed under a source region.

17. The device of claim 10, further comprising a plurality of layers of a second conductivity type formed below the second region and inside the first region.

18. The device of claim 10, wherein the plurality of oxide regions are shaped as rectangles.

19. A method of manufacturing a high voltage MOS device comprising:
forming a first region of a first conductivity type in a substrate;
forming a second region of a second conductivity type in the region of a first conductivity type; and
forming a pattern of field oxide layer over the region of the second conductivity type wherein there are portions of the region of a second conductivity in between the portions of the field oxide layer.

20. The method of claim 19, wherein the step of forming a pattern further comprises allowing the field oxide to consume portions of the second region underlying the field oxide.

21. The method of claim 19, wherein the step of forming a pattern further comprises forming the field oxide layers over portions of the second region.

22. The method of claim 21, further comprising forming a region of linearly varying doping by combining the portions of the second region under the field oxide layer with sections of the second region adjacent to the field oxide in the layer of the second conductivity underlying the field oxide layer and the second region form a region of the second conductivity type with linearly varying doping.

23. The method of claim 19, wherein the step of forming a first region further comprises forming an epitaxial layer.

24. The method of claim 19, wherein the step of forming a first region further comprises forming a well region.

25. The method of claim 24, wherein the step of forming a well region further comprises forming a first region and a second region, the first region having a higher dopant concentration than the second region.

26. The method of claim 19, further comprising the step of forming a diffused region of the second conductivity type, the diffused region formed under a source region.

27. The method of claim 19, further comprising the step of forming a plurality of layers of a second conductivity type below the second region and inside the first region.

28. The method of claim 19, wherein the step of forming a pattern of field oxide layers further comprising forming a pattern of rectangularly shaped field oxide regions.

29. A semiconductor device comprising:
a substrate;
a first region formed by implanting dopants of a first type in the substrate;
a second region formed in the first region by implanting dopants of a second type in the first region; and
a field oxide layer formed at the top of the first region in a pattern such that there are alternating portions of field oxide adjacent to portions of the second region.

30. The semiconductor device of claim 29, wherein the first region comprises a first area and implanting a second area, the first region having a higher dopant concentration than the second region.

31. The semiconductor device of claim 29, wherein a plurality of regions are formed beneath the second region by implanting dopants of a second type.

32. The semiconductor device of claim 29, wherein a layer of insulating material is applied over portions of the second region.

32. The semiconductor device of claim 29, where polysilicon is formed over the portions of the second region adjacent to the field oxide.

34. A method of manufacturing a high voltage MOS device comprising:
forming a first region of a first conductivity type in a substrate;
forming a pattern of field oxide over the region of the first conductivity type, the pattern having a plurality of openings; and
implanting impurities to form a second region of a second conductivity type in the first region of the first conductivity type in the plurality of openings in the pattern of field oxide.

35. The method of claim 34, wherein the step of forming a first region further comprises forming an epitaxial layer.

36. The method of claim 34, wherein the step of forming a first region further comprises forming a well region.

37. The method of claim 36, wherein the step of forming a well region further comprises forming a first area of high dopant concentration and a second area of low dopant concentration.

38. The method of claim 34, further comprising forming diffused region of the second conductivity type, the diffused region formed under a source region.

39. The method of claim 34, further comprising forming a plurality of layers of a second conductivity type formed below the second region and inside the first region.

40. The method of claim 34, wherein the step of forming a pattern of field oxide further comprises forming rectangular shaped areas of the field oxide.

41. The method of claim 35, wherein the step of forming a pattern of field oxide further comprises forming a pattern of field oxide with openings that decrease in size.

42. The method of claim 41, wherein the step of forming a pattern of field oxide with openings that decrease in size further comprises forming laterally varying regions of a second conductivity type.

43. A high voltage MOS device comprising:
a substrate;
a first region formed by impurities of a first conductivity type implanted in the substrate;
a pattern of field oxide having a plurality of openings, formed by growing the field oxide on top of the first region; and
a plurality of islands formed by impurities of a second type implanted through the pattern of field oxide, the islands formed where there are openings in the pattern of field oxide.

44. The high voltage MOS device of claim 43, wherein first region is an epitaxial layer.

45. The high voltage MOS device of claim 43, wherein the first region further is a well region.

46. The high voltage MOS device of claim 45, wherein the well region further comprises a first area formed by an implantation of a first conductivity type and second area formed by an implantation of a first conductivity type, the first area having a higher dopant concentration than the second area.

47. The high voltage MOS device of claim 43, wherein a diffused region of the second conductivity type is formed under a source region inside the first region.

48. The high voltage MOS device of claim 43, further comprising forming rectangular shaped areas of the field oxide.

49. The high voltage MOS device of claim 44, further comprising forming a pattern of field oxide with openings that decrease in size.

50. The high voltage MOS device of claim 49, further comprising forming laterally varying regions of a second conductivity type by implanting impurities through the field oxide openings.

51. A method of forming a high voltage DMOS device comprising:
forming a first region of a first conductivity type in a substrate;
forming a diffused region of a second conductivity in the substrate;
forming a source region of a first conductivity type in the diffused region;
forming a drain region of a first conductivity type in the first region;
forming a pattern of field oxide with multiple openings over the first region; and
forming islands of a second conductivity in the multiple openings.

52. The method of claim 51, wherein the step of forming a first region further comprises forming an epitaxial layer.

53. The method of claim 51, wherein the step of forming a first region further comprises forming a well region.

54. The method of claim 53, wherein the step of forming a well region further comprises forming a first area of and a second area, the first area having a higher dopant concentration than the second area.

55. The method of claim 51, further comprising forming a plurality of layers of a second conductivity type formed below the second region and inside the first region.

56. The method of claim 51, wherein the step of forming a pattern of oxide further comprises forming rectangular shaped areas of the oxide.

57. The method of claim 52, wherein the step of forming a pattern of field oxide further comprises forming a pattern of field oxide with openings that decrease in size.

58. The method of claim 57, wherein the step of forming a pattern of field oxide with openings that decrease in size further comprises forming laterally varying regions of a second conductivity type.
